(19) United States
(12) Patent Application Publication
(10) Pub. No.: US 2019/0226084 A1
(43) Pub. Date: Jul. 25, 2019

(54) DEPOSITION APPARATUS AND DEPOSITION METHOD USING DEPOSITION APPARATUS

(71) Applicant: SAMSUNG DISPLAY CO., LTD., Yongin-si (KR)

(72) Inventors: Sangjin HAN, Seoul (KR); Myungsoo HUH, Suwon-si (KR); Eugene KANG, Suwon-si (KR); Junha PARK, Hwaseong-si (KR); Seongho JEONG, Suwon-si (KR); Jiyoung CHOUNG, Hwaseong-si (KR)

(21) Appl. No.: 16/254,699

(22) Filed: Jan. 23, 2019

(30) Foreign Application Priority Data
Jan. 24, 2018 (KR) 10-2018-0008906

(51) Int. Cl. C23C 16/455

(52) U.S. Cl. CPC C23C 16/4557; H01L 51/001

(57) ABSTRACT

A deposition apparatus includes: a vacuum chamber in which a deposition process is performable; connected to the vacuum chamber: vaporizers in which are vaporizable different deposition materials; and a mixing chamber in which the vaporized different deposition materials are mixable; and within the vacuum chamber: a substrate support on which is supportable a substrate on which the mixed vaporized different deposition materials are deposited in the deposition process; and a spray nozzle which is connected to the mixing chamber and from which the mixed vaporized different deposition materials are sprayable to the substrate in the deposition process. The spray nozzle includes nozzles arranged in a plurality of lines.

This application claims priority to Korean Patent Application No. 10-2018-0008906, filed on Jan. 24, 2018, and all the benefits accruing therefrom under 35 U.S.C. § 119, the contents of which in their entirety are herein incorporated by reference.

### BACKGROUND

### 1. Field

Embodiments of the invention relate to a deposition apparatus, and more particularly, to a deposition apparatus using a surface deposition method.

### 2. Description of the Related Art

Organic light emitting diodes (“OLEDs”) are a light emitting element in which electrons and holes respectively injected through a cathode and an anode are combined in a light emitting layer, which includes an organic material, to emit light of a specific wavelength. The wavelength of the light generated in the OLED may vary depending on the type of the organic material. The OLED display device is one of self-light emitting type display devices which employs such an OLED array as a light source.

When manufacturing such OLEDs, the most important process is a process of forming an organic thin film. In order to form such an organic thin film, vacuum deposition is largely used.

In the vacuum deposition, a substrate, such as a glass substrate, and an evaporation source, such as a point source, which includes a powdery deposition material, are disposed to oppose each other in a chamber, and the powdery deposition material included in the evaporation source is evaporated and sprayed to a surface of the substrate, thereby forming an organic thin film thereon.

As the substrate becomes relatively larger, a linear evaporation source, in place of the evaporation source known as a point source, is used in which the uniformity of thin film is secured for the relatively large-sized substrate.

### SUMMARY

Embodiments of the invention may be directed to a deposition apparatus capable of depositing a plurality of deposition materials in a single vacuum chamber and capable of performing deposition at a relatively high speed, by forming a nozzle unit in a planar shape in the vacuum chamber and connecting the nozzle unit with a plurality of vaporizers disposed outside the vacuum chamber.

According to an embodiment, a deposition apparatus includes: a vacuum chamber in which a deposition process is performable; disposed connected to the vacuum chamber: a plurality of vaporizers in which are vaporizable different deposition materials; and a mixing chamber connected to the plurality of vaporizers and in which the vaporized different deposition materials are mixable; and disposed within the vacuum chamber connected to the plurality of vaporizers and the mixing chamber: a substrate support on which is supportable a substrate on which the mixed vaporized different deposition materials are deposited in the deposition process; and a spray nozzle which is connected to the mixing chamber and from which the mixed vaporized different deposition materials are sprayable to the substrate supported on the substrate support in the deposition process. The spray nozzle includes a plurality of nozzles arranged in a plurality of lines.

The vaporizers may include: a first vaporizer in first deposition materials among the different deposition materials are heatable and vaporizable, connected to the mixing chamber; and a second vaporizer in which a second deposition material different from the first deposition materials among the different deposition materials is evaporable, connected to the mixing chamber to which the first vaporizer is connected.

The first vaporizer may include a plurality of crucibles.

The vaporizers may be disposed outside the vacuum chamber.

The mixing chamber may be disposed outside the vacuum chamber.

A heating wall may be disposed in the vacuum chamber.

The deposition apparatus may further include: a first pipe respectively connecting the vaporizers and the mixing chamber to each other; and a second pipe connecting the mixing chamber and the spray nozzle to each other.

The deposition apparatus may further include: a first heater disposed at the spray nozzle; and a second heater disposed at the first pipe and the second pipe.

The deposition apparatus may further include: a deposition sensor disposed at the first pipe and the second pipe and with which an amount and a pressure of the deposition material moving through the first pipe and the second pipe are sensable.

The spray nozzle may have a shape corresponding to a shape of the substrate.

The spray nozzle may include a first baffle and a second baffle.

Each of the first baffle and the second baffle may include a plate in which a plurality of nozzles is defined passing through a thickness of the plate.

Within each of the first baffle and the second baffle, as a distance from a center portion of the spray nozzle increases, an interval between adjacent nozzles may decrease or a planar size of the plurality of nozzles may increase.

The interval and the size of the nozzles of the first baffle may be different from the interval and the size of the nozzles of the second baffle.

The nozzles of the first baffle may be arranged alternately with the nozzles of the second baffle.

The deposition process may dispose the substrate and the spray nozzle stationary.

The deposition apparatus may further include a transfer unit connected to the substrate support and with which the substrate support is transferrable to a predetermined position.

According to another embodiment, a deposition apparatus includes: a vacuum chamber provided in plurality each connected to: a vaporizer in which are vaporizable: different first deposition materials for forming a single color layered structure on a substrate, and a second deposition material for forming a layer other than the single color layered structure on the substrate, and a mixing chamber connected to the vaporizer and in which the different vaporized deposition materials from the vaporizer are mixable, and disposed within each of the vacuum chambers, a spray nozzle which is connected to the mixing chamber and from which the mixed different vaporized deposition materials are sprayable to the substrate to form the single color layered structure thereon. Within a deposition process of the deposition apparatus, an entirety of the single color layered structure and an entirety of the layer other than the single color layered structure are formable in each of the plurality of vacuum chambers, and at least one of the plurality of vacuum chambers is sequentially used as a preliminary chamber as a deposition process proceeds.

The vaporizer may be disposed outside the vacuum chamber.

The deposition process may dispose the substrate and the spray nozzle stationary.

The foregoing is illustrative only and is not intended to be in any way limiting. In addition to the illustrative embodiments and features described above, further embodiments and features will become apparent by reference to the drawings and the following detailed description.

### BRIEF DESCRIPTION OF THE DRAWINGS

A more complete appreciation of the invention will become more apparent by describing in detail embodiments thereof with reference to the accompanying drawings, where:

FIG. 1 is a cross-sectional view illustrating an embodiment of a deposition apparatus according to the invention;

FIGS. 2(a) through 2(d) are schematic views illustrating another embodiment of a deposition apparatus according to the invention; and

FIGS. 3(a) through 3(h) illustrate cross-sectional views of a layered structure formed using a deposition process using a deposition apparatus according to the invention.

### DETAILED DESCRIPTION

Embodiments will now be described more fully hereinafter with reference to the accompanying drawings. Although the invention may be modified in various manners and have several embodiments, embodiments are illustrated in the accompanying drawings and will be mainly described in the specification. However, the scope of the invention is not limited to the embodiments and should be construed as including all the changes, equivalents and substitutions included in the spirit and scope of the invention.

In the drawings, thicknesses of a plurality of layers and areas are illustrated in an enlarged manner for clarity and ease of description thereof. When a layer, area or plate is referred to as being related to another element such as being “on” another layer, area or plate, it may be directly on the other layer, area, or plate, or intervening layers, areas, or plates may be present therebetween. Conversely, when a layer, area, or plate is referred to as being related to another element such as being “directly on” another layer, area or plate, intervening layers, areas or plates are absent therebetween. Further when a layer, area, or plate is referred to as being related to another element such as being “below” another layer, area or plate, it may be directly below the other layer, area, or plate, or intervening layers, areas or plates may be present therebetween. Conversely, when a layer, area, or plate is referred to as being related to another element such as being “directly below” another layer, area or plate, intervening layers, areas or plates are absent therebetween.

The spatially relative terms “below,” “beneath,” “lower,” “above,” “upper” and the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in the other direction and thus the spatially relative terms may be interpreted differently depending on the orientations.

Throughout the specification, when an element is referred to as being “connected” to another element, the element is “physically connected” or “mechanically connected” to the other element, “fluidly connected” to the other element or “electrically connected” to the other element, with one or more intervening elements interposed therebetween.

The terminology used herein is for the purpose of describing particular embodiments only and is not intended to be limiting. As used herein, the singular forms “a,” “an,” and “the” are intended to include the plural forms, including “at least one,” unless the content clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises,” “comprising,” “includes” and/or “including,” when used in this specification, specify the presence of stated features, integers, steps, operations, elements, and/or components, but do not preclude the presence or addition of one or more other features, integers, steps, operations, elements, components, and/or groups thereof.

It will be understood that, although the terms “first,” “second,” “third,” and the like may be used herein to describe various elements, these elements should not be limited by these terms. These terms are only used to distinguish one element from another element. Thus, “a first element” discussed below could be termed “a second element” or “a third element,” and “a second element” and “a third element” may be termed likewise without departing from the teachings herein.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Unless otherwise defined, all terms used herein (including technical and scientific terms) have the same meaning as commonly understood by those skilled in the art to which this invention pertains. It will be further understood that terms, such as those defined in commonly used dictionaries, should be interpreted as having a meaning that is consistent with their meaning in the context of the relevant art and will not be interpreted in an ideal or excessively formal sense unless clearly defined at the present specification.

Some of the parts which are not associated with the description may not be provided in order to specifically describe embodiments of the invention and like reference numerals refer to like elements throughout the specification.

In conventional deposition apparatuses using a linear evaporation source for forming a relatively thin film, deposition material is stored in a crucible, and a plurality of evaporation holes are defined spaced apart from each other to spray the stored deposition material to a substrate on which the thin film is formed. A conventional evaporation source and deposition apparatus including the same is disclosed, for example, in Korean Patent Publication No. 10-2016-0112293 published on Sep. 28, 2016, the content of which is incorporated herein by reference in its entirety.

However, as the size of the substrate on which a thin film is formed becomes even larger, a relatively larger amount of deposition material is used in forming the thin film. In order to perform a long time deposition process in which the relatively larger amount of deposition material is used in forming the thin film, the crucible may be replaced during the deposition process.

Additional work is performed each time a crucible is replace during such a vacuum deposition process, which consumes a relatively large amount of effort and energy. Furthermore, a considerable time is expended to re-vacuum the chamber, and thereby the overall productivity of the deposition process is lowered.

In addition, in the conventional deposition apparatus, since the plurality of evaporation sources are provided within a space allowed by the vacuum chamber, only a limited number of evaporation sources may be provided, and thus only a limited amount of deposition material may be supplied to the substrate during the deposition process.

In addition, in the aforementioned conventional deposition apparatus, a size of the system is increased in order to secure a moving distance of the linear evaporation source and/or the substrate, and to secure a deposition prevention area and an angle limiting area for forming a composite film. Further, since the aforementioned conventional deposition apparatus has a structure in which one nozzle corresponds to one deposition material, a plurality of process chambers are required to form a plurality of successive films using more than one deposition material.

In addition, in the aforementioned conventional deposition apparatus, an amount of materials that are wasted and not used to be actually deposited on the substrate is relatively large because the deposition material is vaporized regardless of the presence or absence of the substrate, and there is a limit to increasing a deposition rate without denaturalization of the material because the size of the vaporizer is fixed.

A deposition apparatus 100 according to an embodiment of the invention is an apparatus for performing a vacuum deposition process, and there is no particular limitation on the type of deposition materials used with such vacuum deposition process. In an exemplary embodiment, for example, the deposition apparatus 100 may be an apparatus with which a light emitting layer of an organic light emitting diode (“OLED”) is formed using an organic material as a deposition material, or an apparatus with which a thin film constituting an encapsulation layer is formed using a monomer as a deposition material. In addition, the present embodiment is not limited to a deposition apparatus for an OLED, and may be an apparatus with which a thin film constituting another semiconductor element or forming an inorganic thin film is formed.

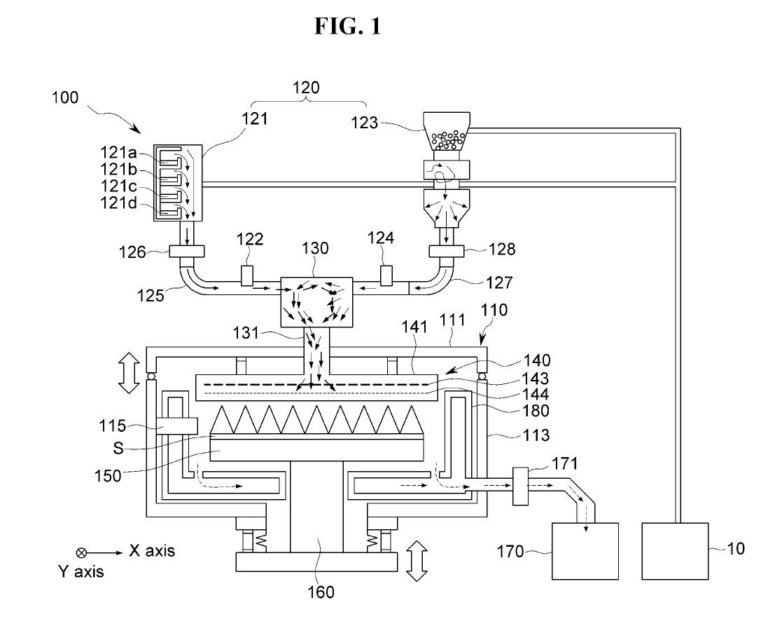

FIG. 1 is a cross-sectional view illustrating an embodiment of a deposition apparatus according to the invention.

Referring to FIG. 1, a deposition apparatus 100 according to an embodiment of the invention includes a vacuum chamber 110, a vaporizer 120, a mixing chamber 130, a nozzle unit (member) 140, a substrate support 150, a transfer unit (member) 160, an exhaust unit (member) 170 and a hot (heating) wall 180.

A deposition process may be performed with the vacuum chamber 110. The vacuum chamber 110 maintains a vacuum state therein during a thin film deposition process for a substrate S. The vacuum chamber 110 may have a three-dimensional a quadrangular box shape or a cylindrical shape. Although the vacuum chamber 110 is described as having a quadrangular box or a cylindrical shape by way of example, embodiments are not limited thereto, and the vacuum chamber 110 may be provided corresponding to the shape of the substrate S.

The vacuum chamber 110 includes an upper vacuum chamber 111 and a lower vacuum chamber 113. The upper and lower vacuum chambers 111 and 113 may connected to each other. However, embodiments are not limited thereto, and the vacuum chamber 110 may be formed unitarily so as to have a single on vacuum chamber.

One side of the vacuum chamber 110 is connected to the exhaust unit 170 for discharging a process gas or organic matter which exists in the chamber from the vacuum chamber 110. A pressure sensor (not illustrated) is disposed inside the vacuum chamber 110 to measure the gas pressure.

The substrate S, the nozzle unit 140 for spraying a deposition material to the substrate S, the substrate support 150 for supporting the substrate S, the transfer unit 160 for transferring the substrate support 150 within an inner area of the vacuum chamber 110, and the hot wall 180 are disposed within the vacuum chamber 110.

In addition, a mask support (not illustrated) for supporting a shadow mask may be provided in the vacuum chamber 110. When a shadow mask is used for red, green and blue (“R, G, and B”) color patterning such as for an OLED according to an embodiment of the invention, a shadow mask having a predetermined pattern corresponding to a pattern of the thin film of the OLED may be placed on a surface of the substrate S of the OLED on which the thin film is to be deposited.

In addition, in the case where the shadow mask is not used for R, G and B color patterning such as for an OLED according to an embodiment of the invention, a shadow mask for R, G and B color patterning may be directly formed on the substrate S using a photoresist (“PR”) material and an exposure process may be performed instead of using a metal shadow mask. In such an embodiment, since the shadow mask is directly formed on the substrate S, such shadow mask is transferred together with the substrate and setting and replacement of shadow masks is obviated, which may maximize facility utilization.

A process of the R, G, and B color patterning of the OLED without using a shadow mask separate from the substrate according to an embodiment of the invention will be described below.

The vaporizer 120 is configured to vaporize the deposition material provided from a material supply unit (supplier) 10. The vaporizer 120 vaporizes a solid or liquid material.

The material supply unit 10 may include a deposition material discharge valve (not illustrated) to supply the deposition material to the vaporizer 120 in a predetermined amount.

The vaporizer 120 includes a first vaporizer 121 for heating and vaporizing at least one deposition material, and a second vaporizer 123 for evaporating the supplied deposition material from the material supply unit 10. The material supply unit 10 may be commonly connected to each of the first and second vaporizers 121 and 123, without being limited thereto. In an embodiment, the material supply unit 10 may be provided in plurality respectively connected to the first and second vaporizers 121 and 123.

The first vaporizer 121 includes a plurality of crucibles 121a, 121b, 121c and 121d for heating and vaporizing a plurality of different deposition materials, respectively.

A plurality of heaters (not illustrated) for supplying heat to the crucibles 121a, 121b, 121c and 121d may be respectively provided in or connected to the plurality of crucibles 121a, 121b, 121c and 121d, and the heater (not illustrated) corresponding to a respective crucible may heat deposition material to be vaporized in the first vaporizer 121.

The plurality of crucibles 121a, 121b, 121c, and 121d may be linearly arranged in one line as illustrated in FIG. 1, but are not limited thereto. In an embodiment, the plurality of crucibles 121a, 121b, 121c, and 121d may be arranged in two or more lines.

Although four crucibles 121a, 121b, 121c, and 121d are illustrated in the drawings for convenience of illustration, embodiments of the deposition apparatus 100 include at least eight crucibles. Since at least eight organic materials are used to realize one color, embodiments of the deposition apparatus 100 include at least eight crucibles in order to vaporize the deposition materials for forming thin films of one color. In an embodiment, the eight crucibles may sequentially in order vaporize the deposition materials for forming thin films of one color, without being limited thereto.

The second vaporizer 123 is configured to evaporate the supplied deposition material from the material supply unit 10. The second vaporizer 123 vaporizes a relatively small amount of deposition material as compared with the first vaporizer 121.

The second vaporizer 123 forms a solid phase powder from the deposition material supplied from the material supply unit 10 to vaporize the supplied deposition material. In an embodiment, for example, an aerosol deposition method may be used to form the solid phase powder. In the aerosol deposition method, a compressed gas is transferred to an aerosol chamber including solid phase powders, the compressed gas transfers the powders floating in the aerosol chamber with a pressure difference, and the floating powders transferred with the pressure difference are sprayed through the nozzle unit 140 provided in the vacuum chamber 110 to deposit the powders such as on the substrate S.

Although the second vaporizer 123 of the present embodiment is described as depositing the deposition material through an aerosol deposition method, other methods may be employed as long as a relatively small amount of deposition material is vaporized as compared to that of the first vaporizer 121.

The first vaporizer 121 may be connected to the mixing chamber 130 by a first pipe 125, and the second vaporizer 123 may be connected to the mixing chamber 130 by a second pipe 127.

The first pipe 125 and the second pipe 127 may include a second heater (not illustrated) that may heat the first pipe 125 and the second pipe 127 to a predetermined temperature so as to substantially prevent condensation of the vaporized deposition material. The second heater (not illustrated) may be common to each of the first and second pipes 125 and 127, or may be provided in plurality respectively for heating the first and second pipes 125 and 127.

In addition, the first pipe 125 and the second pipe 127 may include a temperature measuring unit (not illustrated) capable of measuring the temperatures of the first and second pipes 125 and 127. The temperature measuring unit may measure the temperatures of the first and second pipes 125 and 127 and may control the second heater (not illustrated) based on the measured temperatures. The temperature measuring unit (not illustrated) may be common to each of the first and second pipes 125 and 127, or may be provided in plurality respectively for measuring the temperatures of the first and second pipes 125 and 127.

In addition, the first pipe 125 and the second pipe 127 may include open/close valves 126 and 128, respectively. The open/close valves 126 and 128 may be controlled by a controller (not illustrated) so that the deposition may be performed according to the kind and amount of the deposition material. The controller (not illustrated) may be commonly connected to each of the open/close valves 126 and 128, or may be provided in plurality respectively connected to the open/close valves 126 and 128 for controlling thereof.

The material supply unit 10 may include a deposition material discharge valve (not illustrated) to supply the deposition material from the material supply unit 10 to the vaporizer 120 in a predetermined amount.

At least one deposition sensor 122 and 124 is disposed at the first pipe 125 and the second pipe 127, respectively, so as to sense an amount of and a pressure of the vaporized deposition material moving in the first pipe 125 and the second pipe 127 from the vaporizer 120. The deposition sensors 122 and 124 may be a crystal sensor.

A cross-sectional thickness of a layer deposited on the substrate S may be calculated based on the amount and the pressure of the deposition material sensed by the deposition sensors 122 and 124. In an embodiment, where the substrate S is disposed in a plane defined by first and second directions of an X axis and a Y axis (refer to FIG. 1) crossing each other, the cross-sectional thickness of the layer is defined along a third direction (e.g., vertical in the view of FIG. 1) which crosses each of the first and second directions of the X axis and the Y axis.

In addition, another deposition sensor 115 is disposed in an inner area of the vacuum chamber 110 so as to sense an amount and a pressure of the deposition material that exists in the vacuum chamber 110.

The vaporizer 120 according to an embodiment of the invention is separated from the nozzle unit 140 such as by the first and second pipes 125 and 127 and disposed outside the vacuum chamber 110. Accordingly, a deposition material such as an organic material may be resupplied, recharged or replaced within the deposition apparatus according to one or more embodiment of the invention even during the deposition process, so that the entire deposition process may not be interrupted and may proceed relatively rapidly for increased efficiency thereof.

In general, a conventional linear deposition apparatus includes at least one linear evaporation source disposed in one single deposition chamber, and the linear evaporation source linearly applies a vaporized deposition material to a substrate within such single deposition chamber by a plurality of linearly arranged nozzles. In such a case, in order to form a plurality of successive films from a plurality of vaporized deposition materials, a plurality of single deposition chambers are required respectively corresponding to each deposition material.

On the other hand, the vaporizer 120 connected to a single one vacuum chamber 110 according to one or more embodiment of the invention sequentially supplies a plurality of deposition materials only when a substrate is present in the vacuum chamber 110. Since deposition materials are provided to the substrate only when the substrate is present in the vacuum chamber 110, waste and denaturation of the deposition material may be substantially prevented as compared with the conventional linear deposition apparatus including a plurality of chambers each supplying different deposition materials.

Accordingly, the deposition apparatus according to one or more embodiment of the invention includes one single process chamber (e.g., vacuum chamber 110) connected to a plurality of vaporizers each vaporizing different deposition materials, and may form a plurality of films successively on one substrate in the one single process chamber.

The mixing chamber 130 is connected to the vaporizer 120 and mixes the deposition material selectively supplied from the first vaporizer 121 and the second vaporizer 123. The mixing chamber 130 is connected to the first vaporizer 121 by the first pipe 125 and to the second vaporizer 123 by the second pipe 127.

The mixing chamber 130 uniformly combines the deposition material vaporized at the first vaporizer 121 and the deposition material vaporized at the second vaporizer 123 with each other, and supplies the combination of materials to the nozzle unit 140. In an embodiment, for example, the mixing chamber 130 may combine the deposition material vaporized at the first vaporizer 121 and the deposition material vaporized at the second vaporizer 123 with each other in a ratio of about 99:1, but the ratio of the materials may be changed in embodiments.

The mixing chamber 130 may be connected to the nozzle unit 140 to be described below, by a third pipe 131.

Although the mixing chamber 130 is described as being disposed outside the vacuum chamber 110, the mixing chamber 130 may be disposed in the vacuum chamber 110 according to embodiments.

The nozzle unit 140 sprays the deposition material supplied from the mixing chamber 140, to the substrate S.

The nozzle unit 140 includes a plurality of nozzles arranged in a plurality of lines.

The nozzle unit 140 has a shape and/or planar area corresponding to that of the substrate S on which the deposition material is deposited. In an embodiment, for example, when the substrate S has a quadrangular (planar) shape, the nozzle unit 140 has a quadrangular (planar) shape, and when the substrate S has a circular (planar) shape, the nozzle unit 140 also has a circular (planar) shape.

The nozzle unit 140 may have a planar area corresponding to that of the substrate S. In an embodiment, the planar area of the nozzle unit 140 may be larger than the planar area of the substrate S.

The nozzle unit 140 includes at least one baffle, and may include a plurality of baffles 143 and 144 each including a plurality of nozzles arranged adjacent to each other at a predetermined interval.

Each of the first baffle 143 and the second baffle 144 has a plate shape and includes a plurality of nozzles or openings passing through a respective thickness of the first baffle 143 and the second baffle 144 in a thickness direction of the nozzle unit 140. That is, the plurality of nozzles or openings pass through a respective thickness of the plate of the first baffle 143 and the plate of the second baffle 144. The first baffle 143 may include nozzles having an interval and a diameter that are different from those of the second baffle 144. As illustrated in FIG. 1, the nozzles of the first baffle 143 and the second baffle 144 may each be arranged along a line, e.g., along a surface of the substrate S in the X axis direction. The lines of the nozzles may be arranged along a thickness direction of the nozzle unit 140, e.g., along a flow path of deposition materials through the nozzle unit 140 or along the vertical (third) direction in FIG. 1.

In an embodiment, the plurality of nozzles may be arranged in a matrix form in the first baffle 143 and the second baffle 144, but the disposition other than the matrix form may be applicable as long as the deposition material can be uniformly applied on the substrate S from the nozzle unit 140. As an example, the plurality of nozzles within a baffle are arranged so that an interval therebetween decreases, as a distance from a central portion of the nozzle unit increases, in order to apply the deposition material uniformly at the central portion and other portions along the baffle. As another example, the plurality of nozzles are disposed such that a diameter of the nozzles increases, as a distance from a central portion of the nozzles increases, in order to apply the deposition material uniformly at the central portion and other portions along the baffle.

In addition, the interval and the diameter of the nozzles of the first baffle 143 may be substantially equal to or different from those of the second baffle 144, respectively. In an embodiment, for example, when the nozzle intervals of the first baffle 143 and the second baffle 144 are different from each other, the nozzles of the first baffle 143 and the nozzles of the second baffle 144 are arranged alternately such as along a direction within the plane defined by the first and second directions described above.

Although not illustrated specifically, the nozzle within a baffle corresponds to a portion or opening defined between adjacent lines within each overall dotted line illustrated for the first baffle 143 and the second baffle 144 in FIG. 1. As illustrated by the overall dotted lines in FIG. 1, a size of the nozzle and a spacing between adjacent nozzles is different for the first and second baffles 143 and 144. While the size and spacing of the nozzles is shown along the X axis direction in FIG. 1, it will be understood that such size and spacing of the nozzles may be defined additionally or alternatively along the Y axis.

Accordingly, the nozzle unit 140 may supply the deposition material uniformly to the substrate S disposed in the vacuum chamber 110.

That is, the deposition apparatus 100 according to an embodiment of the invention uses a surface deposition method and uses a stationary film forming method in which the film formation proceeds while the substrate S and the nozzle unit 140 are stationary.

Accordingly, dissimilar to the conventional linear evaporation source, the deposition apparatus according to an embodiment of the invention does not include a deposition prevention area or a deposition area restriction plate for uniformly forming a film over the entire substrate. Accordingly, a relatively high material utilization efficiency (a ratio of a material deposited on the substrate to the consumed deposition material) may be achieved.

In addition, since the deposition apparatus according to one or more embodiment of the invention forms films in one vacuum chamber per color formed from multiple materials, the films may be formed at a relatively high speed at least three times or more as compared to the conventional linear evaporation source in which films are formed in a plurality of vacuum chambers per color formed from multiple materials. Accordingly, the productivity in one or more embodiment of the invention is significantly increased, and the number of deposition chambers for implementing the same production capacity may be reduced to about ⅓ to about ¼ or less as compared with the number of deposition chambers used in the conventional linear evaporation source method.

The nozzle unit 140 includes a first heater 141 for substantially preventing condensation of the deposition material such as at the nozzle unit 140. The first heater 141 includes a temperature measuring unit (not illustrated) capable of measuring the temperatures of the nozzle unit 140. The temperature measuring unit may measure the temperature of the nozzle unit 140 and may control the first heater 141 based on the measured temperatures to adjust the temperature of the nozzle unit 140.

The nozzle unit 140 according to an embodiment of the invention is formed in a planar shape so that when a plurality of organic materials are sequentially formed with a single one nozzle unit 140, reaction between the deposition materials remaining on the first and second pipes 125 and 127 and on the nozzle unit 140 may undesirably occur.

When different deposition materials are sequentially supplied into the vacuum chamber 110, an adsorption preventive material (not illustrated) may be coated on an inner surface of the nozzle unit 140 and/or the first and second pipes 125 and 127 to reduce or substantially prevent the reaction of the film-forming materials and components of the deposition apparatus 100.

The adsorption preventive material may include a metal (e.g., Au), a metal oxide (e.g., Al₂O₃, TiO₂, and Cr₂O₃), or a dielectric material (e.g., SiC, SiOC, SiOₓ, and SiNₓ) which are relatively less reactive with other materials.

In addition, in order to remove substances which may remain reacted or adsorbed to the first and second pipes 125 and 127 and the nozzle unit 140, a purge process may be performed each time the deposition material supplied to the nozzle unit 140 is changed.

The purge process may be applied using an inert high temperature gas (e.g., He, N₂, Ar, etc.) to remove organic materials adsorbed on the surface of the components of the deposition apparatus 100 such as the first and second pipes 125 and 127 and the nozzle unit 140.

The substrate support 150 supports the substrate S in the vacuum chamber 110 in which the deposition process is performed.

The substrate support 150 is provided at an upper portion of an inner area of the vacuum chamber 110 and supports the substrate S that is drawn into the vacuum chamber 110.

The substrate support 150 has a shape corresponding to the shape of the substrate S. In an embodiment, for example, when the substrate S has a circular (planar) shape, the substrate support 150 has a corresponding circular (planar) shape, and when the substrate S has a polygonal (planar) shape, the substrate support 150 has a polygonal (planar) shape.

A temperature controller (not illustrated) for controlling the ambient temperature of the environment surrounding the substrate support 150 may be disposed in or on the substrate support 150.

The transfer unit 160 is connected to a lower portion of the substrate support 150.

The transfer unit 160 is configured to lift the substrate support 150 and place the substrate support 150 at a predetermined position. The transfer unit 160 may be movable within the deposition apparatus 100 to transfer the substrate support 150 in various positions within the vacuum chamber 110

When the shadow mask is used for R, G, and B color patterning of the OLED, the transfer unit 160 may transfer the substrate S up/down and/or left/right directions via transferring the substrate support 150 in the up/down and/or left/right directions so that the substrate S may be aligned with the shadow mask and the pattern thereof.

The exhaust unit 170 is disposed on one side of the vacuum chamber 110 to adjust and/or maintain the pressure of the vacuum chamber 110.

A vacuum/atmospheric pressure adjusting valve 171 may be installed in the exhaust unit 170 to adjust an atmospheric pressure/vacuum state inside of the vacuum chamber 110.

In addition, the exhaust unit 170 discharges the non-deposited deposition material, the adsorption preventive material and/or the inert gas from the inside of the vacuum chamber 110.

The hot wall 180 is provided in the vacuum chamber 110 and is capable of applying heat within the vacuum chamber 110 to maintain the inside of the vacuum chamber 110 at a predetermined temperature or higher. The predetermined temperature or higher within the vacuum chamber 110 substantially prevents the organic (deposition) material from being formed into a film in the vacuum chamber 110 such as at locations other than the desired substrate S. Thus, with the predetermined temperature or higher within the vacuum chamber 110, generation of contaminant particles due to the organic material deposited inside the vacuum chamber 110 as an undesirable film may be substantially prevented.

In the case of an OLED having an R, G, and B independent pixel structure, eight to twelve materials are typically used for forming an organic layer of one single color.

In the case of the conventional linear evaporation source method, at least fourteen chambers are used in order to realize three individual colors of R, G, and B and to achieve the production capacity, for example, an average production time (“TACT”) per substrate of about 60 seconds.

The deposition apparatus according to one or more embodiment of the invention may deposit an entire one single color per one vacuum chamber by successively forming a plurality of films in one process chamber by using the nozzle unit connected to the plurality of vaporizers.

Accordingly, the deposition apparatus according to one or more embodiment of the invention may be employed in a facility for which the average production time (“TACT”) per substrate is about 60 seconds. In such facility, three vacuum chambers may be used for one color, and nine vacuum chambers may be used for three colors, thereby significantly reducing the number of vacuum chambers as compared to a conventional facility using a conventional deposition apparatus and method.

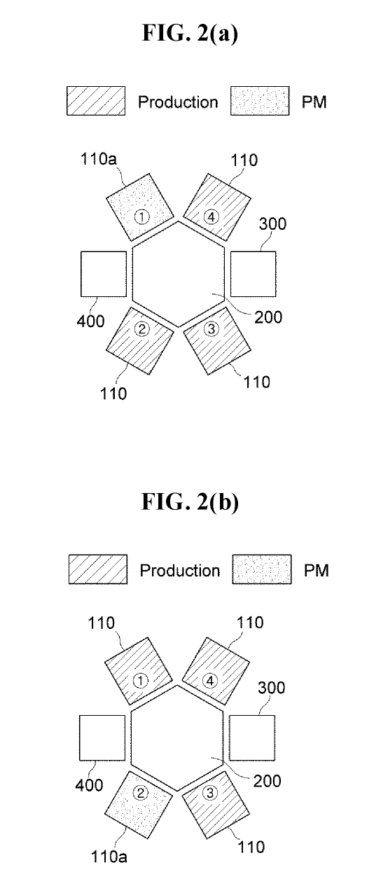

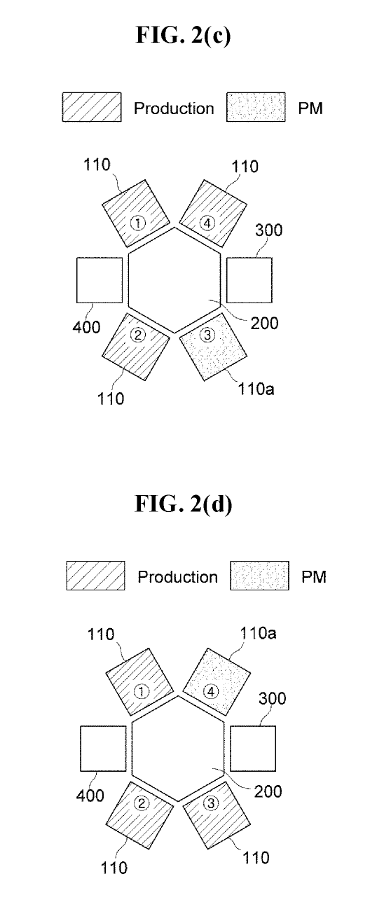

FIGS. 2(a) through 2(d) are schematic views illustrating another embodiment of a deposition apparatus according to the invention.

FIGS. 2(a) through 2(d) respectively illustrate one cluster of vacuum deposition chambers within an overall deposition apparatus, where the same one cluster may perform each operation or process within an overall deposition manufacturing process. The overall deposition apparatus may include a cluster of vacuum deposition chambers provided in plurality, such that each of the plurality of clusters may perform each operation or process within the overall manufacturing process. Although four vacuum chambers are illustrated, the number of vacuum chambers within a same one cluster is not limited thereto.

The one cluster illustrated in each of FIGS. 2(a) through 2(d) includes a plurality of vacuum chambers 110 and 110a. Each of the plurality of vacuum chambers 110 and 110a is connected to a material supply unit 10 (refer to FIG. 1).

In addition, the one cluster may further include a transfer buffer chamber 300 and a rotation buffer chamber 400 for rotating the substrate, respectively adjacent to and in communication with the plurality of vacuum chambers 110 and 110a within the one cluster.

In addition, the one cluster may include, at a center portion of the plurality of vacuum chambers 110 and 110a, a return chamber 200 with which an object on which a material or film is to be deposited, e.g., a substrate, is transferred to another vacuum chamber within the one cluster and/or outside of the one cluster, and may further include a controller (not illustrated) for controlling each component of the one cluster collectively.

The plurality of vacuum chambers 110 and 110a within the one cluster may include four individual vacuum chambers, but the number of vacuum chambers within the one cluster is not limited thereto.

The plurality of vacuum chambers 110 and 110a are disposed adjacent to each other within the one cluster. As the deposition process proceeds, each of the plurality of vacuum chambers 110 and 110a may be used as a preliminary chamber 110a. That is, a same one vacuum chamber within the one cluster may serve as both a preliminary vacuum chamber (110a, ‘PM’ hatching pattern) and a process chamber (110, ‘Production’ hatching pattern 110).

In an embodiment, as process chambers (110, ‘Production’ hatching pattern 110) in a same operation within the overall deposition process, deposition of more than one material for forming one color may be performed in one single vacuum (process) chamber, while deposition of more than one material for forming another color is performed in another single vacuum (process) chamber.

In another embodiment, as a preliminary vacuum chamber (110a, ‘PM’ hatching pattern) in an operation within the overall deposition process, deposition of a material on an object may not be performed, e.g., an inactive deposition chamber. As a process chamber (110, ‘Production’ hatching pattern 110) in a same operation within the overall deposition process, material may be deposited on an object, e.g., an active deposition chamber

Referring to the cluster of chambers in FIG. 2(a) as representing an operation within the deposition process, a first vacuum chamber \textcircled{1} (labeled as 110a) is operated as a preliminary chamber, and a deposition process is performed in second \textcircled{2}, third \textcircled{3}, and fourth \textcircled{4} vacuum chambers (each labeled 110). Vacuum chambers \textcircled{1}, \textcircled{4}, \textcircled{3} and \textcircled{2} are sequentially provided in a clockwise direction within the one cluster, without being limited thereto.

Referring to the same cluster of chambers in FIGS. 2(b), 2(c), and 2(d) as representing other operations within the deposition process, respectively, the second \textcircled{2}, third \textcircled{3} and fourth \textcircled{4} vacuum chambers are sequentially operated as the preliminary chamber (110a) in order of operations represented in (b), (c) and (d) (as indicated by the arrows in FIGS. 2(a) through 2(d)), while the deposition process is performed in the remaining vacuum chambers (110's other than the 110a in each of (b), (c) and (d)).

Referring to FIGS. 1 and 2, the vacuum chamber as a process chamber 110 is connected to a vaporizer 120 including a plurality of vaporizing chambers for vaporizing a deposition material, via a mixing chamber 130 for mixing the deposition material vaporized at the vaporizer 120. In addition, the vacuum chamber as a process chamber 110 includes a nozzle unit 140 for spraying the deposition material supplied from the mixing chamber 130 to the substrate S.

The vaporizer 120 is disposed outside the vacuum chamber as the process chamber 110 and as the preliminary chamber 110a. As a process chamber 110, the deposition proceeds in a state where the substrate S and the nozzle unit 140 are stationary such as relative to each other.

Each of the vacuum chambers with the one cluster as a process chamber 110 has a substantially same structure and function.

The vacuum chamber as the preliminary chamber 110a has a substantially same structure and function as those of the vacuum chamber as a process chamber 110. That is, each of the elements 110 and 110a in FIG. 2(a) through 2(d) may represent a deposition apparatus 100 of FIG. 1. At least one preliminary chamber 110a may be provided per cluster. In an embodiment, each operation within the overall deposition process may include at least one vacuum chamber as a preliminary chamber 110a within one cluster of vacuum chambers.

In a conventional vapor deposition apparatus, only one single vacuum chamber is provided for actively forming one single deposition layer. Accordingly, in the case where the one single vacuum chamber is not available for use, for example, when the vacuum chamber is malfunctioning, or when the alignment state or speed of the substrate drawn into the one single vacuum chamber is unstable, the corresponding cluster including the one signal vacuum chamber or the entire deposition apparatus including such cluster should be stopped.

On the other hand, the deposition apparatus according to one or more embodiment of the invention includes one or more preliminary chamber per a same one cluster, which is configured for active deposition, e.g., as a process chamber. Therefore, the one or more preliminary chamber may replace the vacuum chamber that is not available for use as a process chamber, and thus the deposition may be performed without stopping the cluster including the unavailable vacuum chamber or the deposition apparatus including such cluster.

In addition, since the conventional deposition apparatus forms films a single one color using a plurality of vacuum chambers to apply a plurality of different materials for forming the single one color, the number of OLED panels that may be produced during a TACT time has been limited.

However, according to one or more embodiment of the invention, deposition of more than one material for forming one color may be performed in one single vacuum chamber, while deposition of more than one material for forming another color is performed in another single vacuum chamber, and another deposition material is deposited in a preliminary chamber. Accordingly, an addition apparatus for transferring an object such as a substrate between vacuum chambers and the time for waiting for the start of deposition may be significantly reduced, and a number of substrates on which deposition material may be deposited per cluster in a short time. Accordingly, according to one or more embodiment of the invention, the productivity of an overall manufacturing process including deposition operations may be significantly improved.

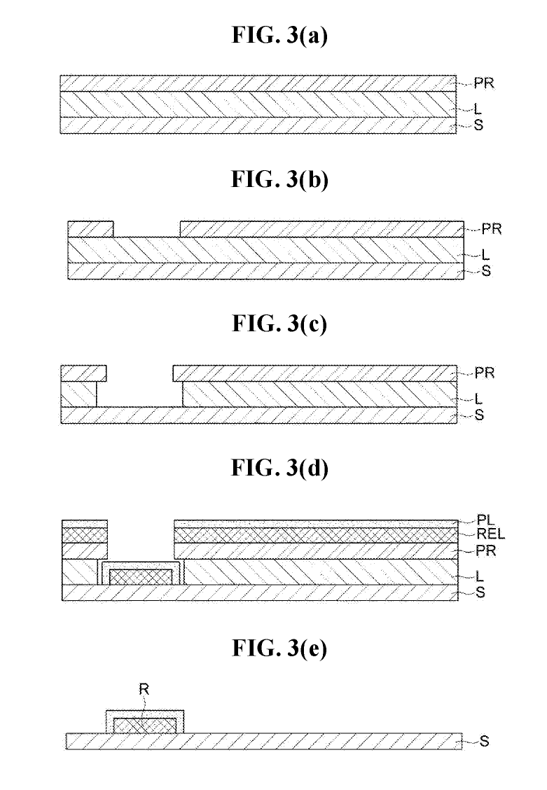

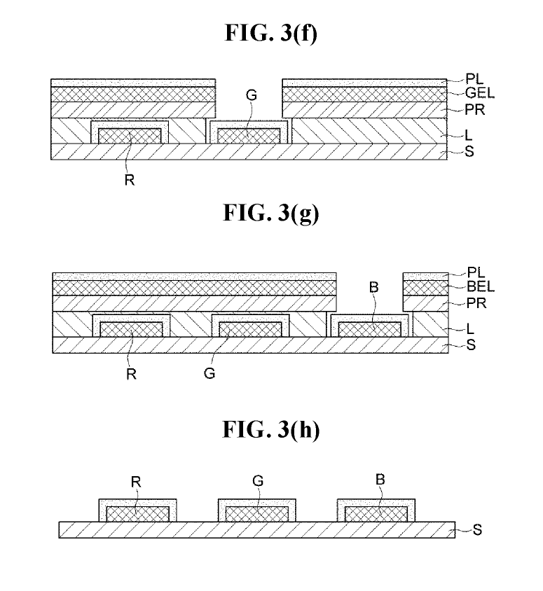

FIGS. 3(a) through 3(h) illustrate cross-sectional views of a layered structure formed using a deposition process using a deposition apparatus according to the invention. More particularly, FIGS. 3(a) through 3(h) illustrate cross-sectional views of a layered structure formed by a process of patterning R, G, and B colors of an OLED structure according to an embodiment of the invention.

In the case where a shadow mask separate from a substrate is not used for R, G, and B color patterning of OLEDs according to an embodiment of the invention, a shadow mask for R, G and B color patterning may be directly formed on the substrate such as using a photoresist (“PR”) material and an exposure process. With such a shadow mask formed direction on the substrate, such mask may move together with the substrate during the color patterning, exposure process, transfer within a deposition apparatus, etc. In such an embodiment, setting and replacement of shadow masks within a deposition apparatus are obviated, which may maximize facility utilization.

In the process of patterning R, G and B colors such as for use in an OLED without using a shadow mask separate from a substrate S of the OLED, a (first) lift off layer L is formed on the substrate S and a (first) photoresist (“PR”) coating is performed, as illustrated in FIG. 3(a).

A PR patterning is performed such as by photolithography and development processes, as illustrated in FIG. 3(b). The patterning of the PR forms an opening in the PR which is defined by portions of the PR. As illustrated in FIG. 3(b), the underlying lift off layer L is exposed to outside the layered structure at the opening in the PR.

The lift off layer L is patterned such as by an etching process, as illustrated in FIG. 3(c). More particularly, the patterned PR layer may be used as an etching mask to remove a portion of the lift off layer L at the opening defined by portions of the PR layer. The patterning of the lift off Layer forms an opening in the lift off layer L which is defined by portions of the lift off layer L. As illustrated in FIG. 3(c), the underlying substrate is exposed to outside the layered structure at the opening in the lift off layer L corresponding to the opening in the PR layer. The openings in the lift off layer L and the PR layer may be aligned with each other to form a single continuous opening of the layered structure.

The etching process for patterning the lift off layer L may be a dry etching process or a wet etching process.

A red emitting layer REL and a (first) passivation layer PL are formed on the layered structure, as illustrated in FIG. 3(d). The forming of the red emitting layer REL and the passivation layer PL disposes portions of these layers in the aligned openings defined in the lift off layer L and the PR layer. At the (first) aligned openings, the portions of these layers in the aligned openings may be spaced apart from sides of the lift off layer L and the PR layer and remaining portions of the red emitting layer REL and the passivation layer PL.

The lift off layer L is removed from the underlying substrate S such as by a wet process to form an independent pixel (structure) R, as illustrated in FIG. 3(e). Together with the lift off layer L, the PR layer and remaining portions of the red emitting layer REL and the passivation layer PL not in the aligned openings may be removed from the underlying substrate S. The independent pixel R may include a layer or structure of the OLED with which a red color light is generated and/or emitted at light-emitting area or image display area of the OLED.

The processes illustrated in 3(a), 3(b), 3(c) and 3(d) are repeated to form a green emitting layer GEL and a (second) passivation layer PL, and then the (second) lift off layer L is removed together with the (second) PR layer and remaining portions of the red emitting layer REL and the (second) passivation layer PL not in the (second) aligned openings, such as by a wet process, to form an independent pixel (structure) G, as illustrated in FIG. 3(f). The independent pixel G may include a layer or structure of the OLED with which a green color light is generated and/or emitted at light-emitting area or image display area of the OLED.

In addition, the processes 3(a), 3(b), 3(c), and 3(d) are repeated to form a blue emitting layer BEL and a (third) passivation layer PL, and then the (third) lift off layer L is removed together with the (third) PR layer and remaining portions of the red emitting layer REL and the (third) passivation layer PL not in the aligned openings such as by a wet process to form an independent pixel (structure) B, as illustrated in FIG. 3(g). The independent pixel B may include a layer or structure of the OLED with which a blue color light is generated and/or emitted at light-emitting area or image display area of the OLED.

Once the processes 3(a), 3(b), 3(c), and 3(d) are repeated to form various color independent pixel structures, the R, G, and B independent pixel structures may be provided for the OLED.

Referring to FIG. 1, all of the processes illustrated in FIGS. 3(a) to 3(e) for forming one color structure may be performed in a same deposition apparatus 100, and more particularly, in a same one vacuum chamber 110. In an embodiment, the organic materials for respectively forming an independent pixel structure of a single color in FIGS. 3(a) to 3(e) may be disposed within respective crucibles (refer to 121a-121d in FIG. 1) of a first vaporizer (121 in FIG. 1) and/or in a material supply unit (10 in FIG. 1).

In forming the one color structure in the same one vacuum chamber 110 of FIG. 1, a surface deposition method uses a stationary film forming method in which films of the one color structure are respectively formed while the substrate S and the nozzle unit (140 in FIG. 1) are stationary with respect to each other and/or within the deposition apparatus (100 in FIG. 1). Furthermore, the different materials for forming the films of the one color structure are sequentially supplied to the substrate S only when the substrate S is present in the same one vacuum chamber 110, to reduce waste and denaturation of the deposition materials.

In an embodiment, all of the processes illustrated in FIGS. 3(a) to 3(e) for forming one color structure may be performed in a respective one process chamber 110 within a cluster of vacuum chambers illustrated in FIGS. 2(a) to 2(d). Where there are multiple process chambers 110 functioning in a single cluster of vacuum chambers (any of FIGS. 2(a) to 2(d)), each process chamber 110 may be forming a color structure at the same time as each other, without being limited thereto. The color structures formed by the each process chamber within the single cluster may be of a same color or different colors.

In an embodiment, as a color structure formed on the substrate S is completed by a process chamber 110, the return chamber 200, the transfer buffer chamber 300 and/or the rotation buffer chamber 400 may be used to transfer the substrate S with the completed color structure, to rotate such substrate S, etc. for further processing within the same cluster of vacuum chambers or a different cluster of vacuum chambers.

In forming the one color structure in the same one process chamber 110 of FIGS. 2(a) to 2(d), a surface deposition method uses a stationary film forming method in which films of the one color structure are respectively formed while the substrate S and the nozzle unit (140 in FIG. 1) are stationary with respect to each other and/or within the deposition apparatus (100 in FIG. 1 as represented by 110 in FIGS. 2(a) to 2(d)). Furthermore, the different materials for forming the films of the one color structure are sequentially supplied to the substrate S only when the substrate S is present in the same one process chamber 110, to reduce waste and denaturation of the deposition materials.

According to still another embodiment of the invention, when the surface deposition method according to an embodiment of the invention is applied to the process of manufacturing OLEDs that does not use a shadow mask separate from the substrate S, there is no production loss factor such as shadow mask replacement, organic material filling/replacement, and periodic replacement of adsorption preventive plates. Thus, a facility operation rate for a facility employing a deposition apparatus and method of using such deposition apparatus according to the invention may be substantially maximized.

As set forth hereinabove, in the deposition apparatus according to one or more embodiments of the invention, dissimilar to the conventional linear source, a deposition prevention area or a deposition area restricting plate are obviated to form a uniform film over the entire substrate. Thus, a relatively high material utilization efficiency (a ratio of a material deposited on the substrate to the consumed deposition material) may be achieved.

In the deposition apparatus according to one or more embodiments of the t invention, one nozzle unit is connected to a plurality of vaporizers, such that a plurality of layers may be successively formed in one single process chamber, and deposition of one color may be performed per one single vacuum chamber. Accordingly, the number of vacuum chambers according to one or more embodiments of the t invention may be significantly reduced as compared with the conventional linear deposition apparatus.

The deposition apparatus according to one or more embodiments of the invention may perform a non-stop deposition including successively forming a plurality of layers in one single process chamber. Thus, an additional apparatus for transferring and the time for waiting for the start of deposition for a subsequent layer may be significantly reduced, and a number of substrates on which materials may be deposited per cluster in a relatively short time. Accordingly, the productivity may be significantly improved by such non-stop deposition and the reduction in time for transferring and waiting described above.

While the invention has been illustrated and described with reference to the embodiments thereof, it will be apparent to those of ordinary skill in the art that various changes in form and detail may be made thereto without departing from the spirit and scope of the invention.

What is claimed is:

1. A deposition apparatus comprising:
a vacuum chamber in which a deposition process is performable;
disposed connected to the vacuum chamber:
a plurality of vaporizers in which are vaporizable different deposition materials; and
a mixing chamber connected to the plurality of vaporizers and in which the vaporized different deposition materials are mixable; and
disposed within the vacuum chamber connected to the plurality of vaporizers and the mixing chamber:
a substrate support on which is supportable a substrate on which the mixed vaporized different deposition materials are deposited in the deposition process; and
a spray nozzle which is connected to the mixing chamber and from which the mixed vaporized different deposition materials are sprayable to the substrate supported on the substrate support in the deposition process,
wherein the spray nozzle comprises a plurality of nozzles arranged in a plurality of lines.

2. The deposition apparatus of claim 1, wherein the plurality of vaporizers comprises:
a first vaporizer in first deposition materials among the different deposition materials are heatable and vaporizable, connected to the mixing chamber; and
a second vaporizer in which a second deposition material different from the first deposition materials among the different deposition materials is evaporable, connected to the mixing chamber to which the first vaporizer is connected.

3. The deposition apparatus of claim 2, wherein the first vaporizer comprises a plurality of crucibles in which the first deposition materials are respectively heatable and vaporizable.

4. The deposition apparatus of claim 1, wherein the plurality of vaporizers is disposed outside the vacuum chamber to which the plurality of vaporizers is connected.

5. The deposition apparatus of claim 1, wherein the mixing chamber is disposed outside the vacuum chamber to which the mixing chamber is connected.

6. The deposition apparatus of claim 1, further comprising a heating wall which is disposed in the vacuum chamber and with which a temperature within the vacuum chamber is adjustable.

7. The deposition apparatus of claim 1, further comprising:
a first pipe respectively connecting the plurality of vaporizers and the mixing chamber to each other; and
a second pipe connecting the mixing chamber and the spray nozzle to each other.

8. The deposition apparatus of claim 7, further comprising:
a first heater disposed at the spray nozzle, with which a temperature of the spray nozzle is controllable; and
a second heater disposed at the first pipe and the second pipe, with which a temperature of the first pipe and the second pipe are respectively controllable.

9. The deposition apparatus of claim 7, further comprising:
a deposition sensor disposed at the first pipe and the second pipe, with which an amount and a pressure of the deposition material moving through the first pipe and the second pipe are sensable.

10. The deposition apparatus of claim 1, wherein the spray nozzle disposed within the vacuum chamber has a shape corresponding to a shape of the substrate supported on the substrate supporter within the vacuum chamber.

11. The deposition apparatus of claim 1, wherein the spray nozzle comprises a first baffle and a second baffle disposed adjacent to each other along a flow path of deposition material through the spray nozzle.

12. The deposition apparatus of claim 11, wherein each of the first baffle and the second baffle comprises a plate in which a plurality of nozzles is defined passing through a thickness of the plate.

13. The deposition apparatus of claim 12, wherein within each of the first baffle and the second baffle, as a distance from a center portion of the spray nozzle increases, an interval between adjacent nozzles decreases or a planar size of the plurality of nozzles increases.

14. The deposition apparatus of claim 13, wherein the interval between adjacent nozzles and the planar size of the nozzles of the first baffle are different from the interval between adjacent nozzles and the planar size of the nozzles of the second baffle.

15. The deposition apparatus of claim 14, wherein the nozzles of the first baffle are arranged alternately with the nozzles of the second baffle.

16. The deposition apparatus of claim 1, wherein the deposition process disposes the substrate and the spray nozzle stationary.

17. The deposition apparatus of claim 1, further comprising a transfer unit connected to the substrate support and with which the substrate support is transferrable to a predetermined position.

18. A deposition apparatus comprising:
a vacuum chamber provided in plurality each connected to:
a vaporizer in which are vaporizable:
different first deposition materials for forming a single color layered structure on a substrate, and
a second deposition material different from the first deposition materials, and
a mixing chamber connected to the vaporizer and in which the different vaporized deposition materials from the vaporizer are mixable, and
disposed within each of the vacuum chambers, a spray nozzle which is connected to the mixing chamber and from which the mixed different vaporized deposition materials are sprayable to the substrate to form the single color layered structure thereon,
wherein within a deposition process of the deposition apparatus,
an entirety of the single color layered structure and an entirety of the layer other than the single color layered structure are formable in each of the plurality of vacuum chambers, and
at least one of the plurality of vacuum chambers is sequentially used as a preliminary chamber as a deposition process proceeds.

19. The deposition apparatus of claim 18, wherein the vaporizer is disposed outside the vacuum chamber to which the vaporizer is connected.

20. The deposition apparatus of claim 18, wherein the deposition process disposes substrate and the spray nozzle stationary.
